(19) United States
(12) Patent Application Publication
(10) Pub. No.: US 2017/0092835 A1
(43) Pub. Date: Mar. 30, 2017

(54) CERAMIC DEVICE AND JOINED BODY

(71) Applicant: NGK INSULATORS, LTD., Nagoya-City (JP)

(72) Inventors: Masayuki UETANI, Kasugai-Shi (JP); Takeshi KAKU, Komaki-Shi (JP); Yuhji UMEDA, Iwakura-Shi (JP)

(73) Assignee: NGK INSULATORS, LTD., Nagoya-City (JP)

(21) Appl. No.: 15/375,538

(22) Filed: Dec. 12, 2016

Related U.S. Application Data
(63) Continuation of application No. PCT/JP2015/066957, filed on Jun. 12, 2015.

(30) Foreign Application Priority Data
Jun. 17, 2014 (JP) 2014-123947

(51) Int. Cl. H01L 41/047

(52) U.S. Cl. CPC H01L 41/0477; H01L 41/0472

(57) ABSTRACT

Provided is a piezoelectric device which has high reliability for the joint between an external electrode and low-melting-point solder. This piezoelectric device is a fired body including a main body part and an external electrode. The external electrode includes a surface electrode that covers upper and lower surfaces of the main body part, and a side-surface electrode that covers a side surface of the main body part and makes a connection to the surface electrode. This piezoelectric device is obtained by co-firing all of constituent members. The surface electrode is configured to include platinum (Pt) or palladium (Pd). The side-surface electrode is also configured to include platinum (Pt) or palladium (Pd). In addition, the side-surface electrode contains gold (Au). The content ratio of gold in the side-surface electrode is preferably 3 to 20 weight %.

### BACKGROUND OF THE INVENTION

Field of the Invention

The present invention relates to a ceramic device, and more particularly, a ceramic device that functions as a piezoelectric device. The piezoelectric device is also referred to as a piezoelectric/electrostrictive device.

Description of the Background Art

As an example of this type of piezoelectric device, WO 2012/132661 discloses a piezoelectric device 800 that is a fired body including a main body part 810 and an external electrode 811 as shown in FIG. 11. In the piezoelectric device 800 shown in FIG. 11, the main body part 810 is a laminated body that has piezoelectric layers 820 and internal electrodes 821 laminated alternately. The internal electrodes 821 include internal electrodes 821 A, 821 B. The external electrode 811 includes a pair of surface electrodes 840A, 840B partially covering an upper surface 860 of the main body part 810, and a pair of side-surface electrodes 850A, 850B at least partially covering corresponding side surfaces 870A, 870B of the main body part 810, and making connections to the corresponding internal electrodes 821A 821B and the surface electrodes 840A, 840B. Typically, the external electrode 811 (surface electrodes 840A, 840B, and side-surface electrodes 850A, 850B) and the internal electrodes 821 are configured to include platinum (Pt) or palladium (Pd) (hereinafter, referred to as “platinum or the like”). This is based on the fact that platinum or the like has the property of “being high in melting point and less likely to be oxidized (thus, able to be fired stably in an oxygen atmosphere without being oxidized).”

This type of piezoelectric device has been actively developed as an element for controlling the position of an optical lens (for example, an ultrasonic motor for an auto focus or zoom for a camera), a position control element for an element for reading and/or writing magnetic information or the like (for example, an actuator for a magnetic head in a hard disc drive), or a sensor that converts mechanical vibrations to electrical signals.

### SUMMARY OF THE INVENTION

Now, the piezoelectric device 800 shown in FIG. 11 may be, for example, mounted on substrates 910A, 910B with the use of solder parts 920A, 920B, as shown in FIG. 12. In the example shown in FIG. 12, while both ends 880A, 880B of a lower surface 861 of the piezoelectric device 800 are placed respectively on upper surfaces 950A, 950B of opposed ends 940A, 940B of a pair of substrates 910A, 910B located away from each other, the pair of side-surface electrodes 850A, 850B of the piezoelectric device 800 and the ends 940A, 940B of the pair of substrates 910A, 910B are joined and fixed with the use of the solder parts 920A, 920B. Joining and fixing are performed to the copper terminals 930A, 930B.

The melting point of solder vary greatly depending on the composition (substances constituting the solder) of the solder, and there is solder with a relatively high melting point (for example, 200 to 250° C., typically composed of tin (Sn), copper (Cu), silver (Ag), and so on), as well as solder with a relatively low melting point (for example, lower than 200° C., typically composed of tin (Sn), bismuth (Bi), silver (Ag), and so on). Hereinafter, the “solder with a melting point lower than 200° C.” is particularly referred to as “low-melting-point solder.”

As mentioned above, when the side-surface electrodes of the piezoelectric device and the substrates are joined and fixed with the use of the solder, with the use of low-melting-point solder, the joining step mentioned previously can be carried out through the use of the (melted) solder at a relatively low temperature. Therefore, the amount of heat transferred from the solder to the substrates is relatively small in this step. Accordingly, the following advantages are provided.

First, low heat-resistance materials can be used for the substrates and the parts provided on the substrates. As a result, a wider choice of materials is provided. Secondly, thermal stress can be reduced which is generated in the substrates and the parts provided on the substrates in the previously mentioned step, and the possibility of crack generation or the like in the substrates and the parts can be reduced. As a result, the electrical disconnection on the substrate due to the cracks or the like are less likely to occur. Thirdly, when an adhesive containing an epoxy resin is used for the substrates, the treatment of curing the adhesive containing the epoxy resin can also be carried out simultaneously in the step. As a result, the number of steps required for the whole work can be reduced. Fourth, when the side-surface electrodes of the piezoelectric device with the piezoelectric layers (piezoelectric material) polarized are joined with the substrates, the piezoelectric layers (piezoelectric material) are less likely to be depolarized in the step. As a result, the number of steps required for the whole work can be reduced.

On the other hand, the use of the low-melting-point solder also causes the following problem. More specifically, in general, low-melting-point solder has relatively low wettability to platinum or the like. Thus, when the side-surface electrodes of the piezoelectric device are composed of only platinum or the like, the (melted) low-melting-point solder is less likely to spread on the surfaces of the side-surface electrodes. Therefore, the joint area between the side-surface electrodes and the low-melting-point solder is reduced, thereby probably resulting in decreased reliability for the joint between the side-surface electrodes and the low-melting-point solder. Improving the reliability for the joint between the side-surface electrodes (the external electrode) and the low-melting-point solder is now desired.

An object of the present invention is to provide a ceramic device (piezoelectric device) which has high reliability for the joint between the external electrode and low-melting-point solder.

In order to achieve the object mentioned above, a feature of a ceramic device (piezoelectric device) according to the present invention is that the external electrode is configured to include (as a main material) platinum or the like (platinum (Pt) or palladium (Pd)), and the external electrode (typically, the side-surface electrodes) contains gold (Au). In this regard, the external electrode (the surface electrodes+the side-surface electrodes) and the internal electrodes can be configured from the same material (that is, platinum or the like+gold). The electrodes including gold may be only the side-surface electrodes, or only the surface electrodes. The electrodes to be jointed with low-melting-point solder are configured to include gold in addition to platinum or the like. In addition, the main body part and the external electrode can be co-fired.

It has been determined that the configuration mentioned above improves reliability for the joint between the external electrode and the low-melting-point solder, as compared with when the external electrode (typically, the side-surface electrodes) of the ceramic device (piezoelectric device) is composed of only platinum or the like (details will be described later). This is assumed to be based on the following reason.

More specifically, as can be easily understood from a phase diagram (not shown) of gold (Au) and tin (Sn), it is known that in the case of gold (Au) in contact with tin (Sn) in the low-melting-point solder, gold and tin form an alloy phase even at a relatively low temperature on the order of 200° C.

Therefore, in the case of the external electrode composed of platinum or the like with gold therein as in the configuration mentioned above, when the melted low-melting-point solder at approximately 200° C. comes into contact with the surface of the external electrode, the gold in the external electrode can be dissolved in the melted low-melting-point solder. Due to the solution of gold, the platinum or the like present around the dissolved gold is also more likely to be dissolved in the melted low-melting-point solder. As a result, a compound layer including at least tin and platinum or the like can be formed at the joint part between the external electrode and the low-melting-point solder. The formation of this compound layer is assumed to improve the reliability for the joint between the external electrode and the low-melting-point solder. In other words, the gold in the external electrode is assumed to function as “an aid that dissolves platinum or the like in the external electrode to form a compound layer,” thereby improving the reliability for the joint between the external electrode and the low-melting-point solder.

The configuration mentioned above improves reliability for the joint between the external electrode and the low-melting-point solder, as compared with when the external electrode of the ceramic device (piezoelectric device) is composed of only platinum or the like.

In the piezoelectric device mentioned above, the content ratio of gold in the external electrode is suitably 3 to 20 weight %. It has been determined that this content ratio further improves reliability for the joint between the external electrode and the low-melting-point solder, as compared with when the ratio fails to fall within the range (details will be described later).

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view of a piezoelectric device according to a preferred embodiment of the present invention;

FIG. 2 is a cross-sectional view taken along the line 2-2 of the piezoelectric device shown In FIG. 1;

FIG. 3 is a view illustrating a cutting aspect in extracting a large number of piezoelectric device corresponding parts in the same step by cutting a large laminated body formed on a base material;

FIG. 4 is a view illustrating an aspect of the large number of piezoelectric device corresponding parts extracted on the base material by the cutting;

FIG. 5 is a first view illustrating a process for manufacturing the piezoelectric device shown in FIG. 1;

FIG. 6 is a second view illustrating a process for manufacturing the piezoelectric device shown in FIG. 1;

FIG. 7 is a view of the piezoelectric device shown in FIG. 1, mounted on substrates with the use of solder;

FIG. 8 is a cross-sectional view of “the piezoelectric device mounted on the substrates,” shown in FIG. 7, which corresponds to FIG. 2;

FIG. 9 is a view illustrating an example of a sample for use in an experiment before reflow;

FIG. 10 is a view illustrating an example of the sample for use in the experiment after the reflow;

FIG. 11 is a view of a conventional piezoelectric device, which corresponds to FIG. 1; and

FIG. 12 is a view of the conventional piezoelectric device mounted on substrates with the use of solder.

### DESCRIPTION OF THE PREFERRED EMBODIMENTS

A preferred embodiment of a piezoelectric device according to the present invention will be described below with reference to the drawings.

(Configuration)

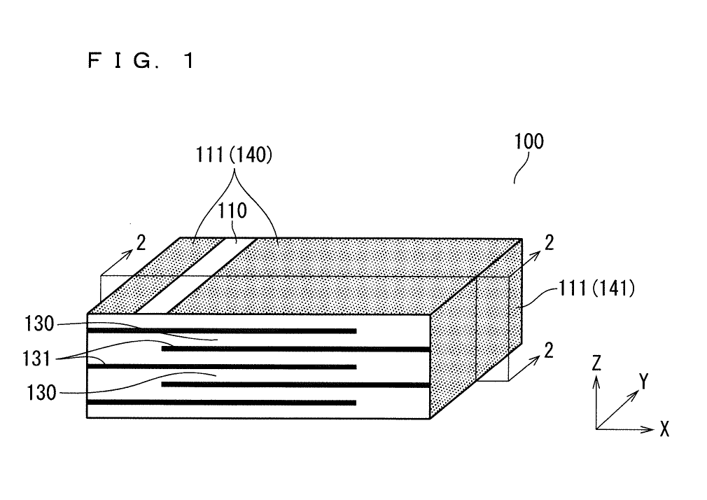

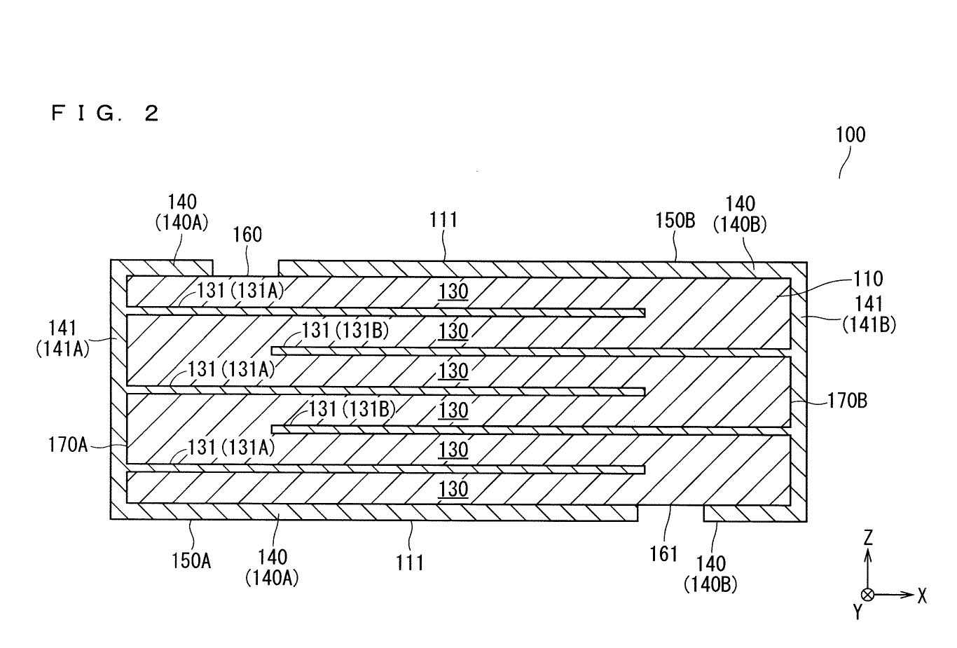

As shown in FIG. 1 and FIG. 2 that is a cross-sectional view taken along the line 2-2 of FIG. 1, a piezoelectric device 100 according to the present preferred embodiment is a fired body, which includes a main body part 110 of a rectangular solid-like shape, and an external electrode 111 provided on the main body part 110 to at least partially cover the surface of the main body part 110.

The main body part 110 is a laminated body which includes multiple (6 in this example) piezoelectric layers 130 of a piezoelectric material, and multiple (5 in this example) layered internal electrodes 131, and where the piezoelectric layers 130 are located as an uppermost layer and a lowermost layer, and the piezoelectric layers 130 and the internal electrodes 131 are laminated alternately. The piezoelectric layers 130 and the internal electrodes 131 are laminated parallel to each other. The size of the main body part 110 (fired) is, for example, 0.2 to 10.0 mm in width (x-axis direction), 0.1 to 10.0 mm in depth (y-axis direction), and 0.01 to 10.0 mm in height (z-axis direction). The thickness (z-axis direction) of each of the piezoelectric layers 130 (fired) is 1.0 to 100.0 μm, and the thickness (z-axis direction) of each of the internal electrodes 131 (fired) is 0.3 to 5.0 μm.

As shown in FIG. 2, the external electrode 111 includes a surface electrode 140 partially covering upper and lower surfaces 160, 161 of the main body part 110, and a side-surface electrode 141 partially covering side surfaces 170A, 170B of the main body 110. The side-surface electrode 141 is electrically connected to the internal electrodes 131 and the surface electrode 140. More specifically, (three) internal electrodes 131A, a surface electrode 140A, and a side-surface electrode 141A (hereinafter, referred to collectively as a “first electrode group 150A”) are electrically connected to each other, whereas (two) internal electrodes 131 B, a surface electrode 140B, and a side-surface electrode 141B (hereinafter, referred to collectively as a “second electrode group 150B”) are electrically connected to each other.

The first and second electrode groups 150A, 150B are connected with the piezoelectric layers 130 interposed therebetween as insulators, and thus electrically insulated from each other. In other words, the (three) internal electrodes 131A electrically connected to each other and (two) internal electrodes 131B electrically connected to each other constitute a comb-like electrode. The surface electrode 140 (fired) is 0.5 to 10.0 μm in thickness, whereas the side-surface electrode 141 (fired) is 0.5 to 10.0 μm in thickness. It is to be noted that the layer number of internal electrodes is 5 in this example, but not particularly limited (which may be zero).

In this piezoelectric device 100, the deformation amount of the piezoelectric layers 130 (thus, the main body part 110) can be controlled by adjusting the potential difference applied between the first and second electrode groups 150A, 150B. Through the use of this principle, the piezoelectric device 100 can be used as an actuator that controls the position of an object. Examples of the object include optical lenses, magnetic heads, and optical heads. In addition, in this piezoelectric device 100, the potential difference produced between the first and second electrode groups 150A, 150B varies depending on the deformation amount of the piezoelectric layers 130 (thus, the main body part 110). Through the use of this principle, the piezoelectric device 100 can be used as various types of sensors such as an ultrasonic sensor, an acceleration sensor, an angular velocity sensor, a shock sensor, and a mass sensor.

It is suitable to adopt, as a material of the piezoelectric layers 130 (piezoelectric material), piezoelectric ceramic, electrostrictive ceramic, ferroelectric ceramic, or antiferroelectric ceramic. Specific materials include ceramics containing, as a single material or a mixture, lead zirconate, lead titanate, lead magnesium niobate, lead nickel niobate, lead zinc niobate, lead manganese niobate, lead antimony stannate, lead manganese tungstate, lead cobalt niobate, barium titanate, sodium bismuth titanate, potassium sodium niobate, and strontium bismuth tantalate.

The materials of the external electrode 111 (the surface electrode 140 and the side-surface electrode 141) and the internal electrodes 131 (electrode materials) are preferably composed of metals that are solid at room temperature and excellent in electrical conductivity. Specifically, the external electrode 111 (the surface electrode 140 and the side-surface electrode 141) and the internal electrodes 131 are composed of platinum (Pt) or palladium (Pd), or an alloy thereof. This is based on the fact that platinum or palladium has the property of “being high in melting point and less likely to be oxidized (thus, able to be fired stably in an oxygen atmosphere without being oxidized).” It is to be noted that the surface electrode 140 and the internal electrodes 131 may be composed of a single element metal such as aluminum, titanium, chromium, iron, cobalt, nickel, copper, zinc, niobium, molybdenum, ruthenium, rhodium, silver, tin, tantalum, tungsten, iridium, and lead, or an alloy thereof. However, from the perspective of co-firing with the main body part 110, the surface electrode 140 and the internal electrodes 131 are preferably composed of platinum (Pt) or palladium (Pd), or an alloy thereof, as with the side-surface electrode 141.

In addition, in particular, the side-surface electrode 141 contains gold (Au). The content ratio of gold in the side-surface electrode 141 will be described later. The surface electrode 140 and the internal electrodes 131 may also contain gold.

(Manufacturing Method)

Next, a method for manufacturing the piezoelectric device mentioned above will be described briefly. Hereinafter, the state of “unfired” is indicated by the addition of the term “green” to the name of a corresponding member, or the addition of the symbol “g” to the end of a sign for a corresponding member.

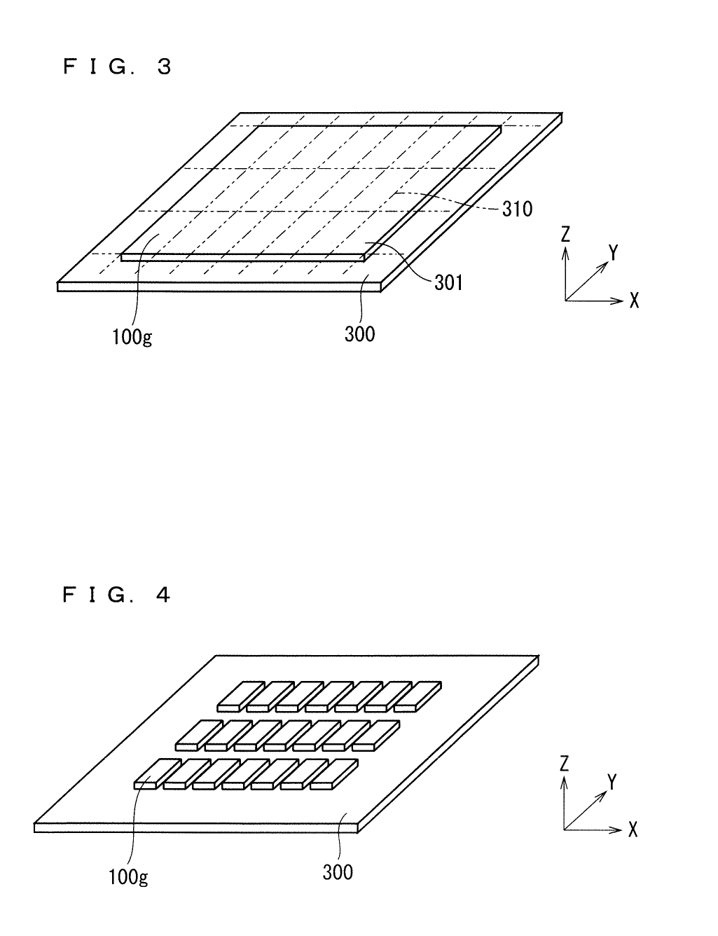

In this example, first, as shown in FIG. 3, on a flat-plate base material 300, a large sheet of green laminated body 301 is formed which includes multiple (3×7) parts corresponding to piezoelectric devices (hereinafter, referred to as “green piezoelectric device corresponding parts”) 100g arrayed in a matrix form at predetermined intervals. This large green laminated body 301 includes green laminated body parts 110g corresponding to the main body part 110, and green electrode films 140g, 140g corresponding to the surface electrode 140, which are formed on upper and lower surfaces 160g, 161g of the parts 110g.

Each of the green laminated body parts 110g corresponding to the main body part 110 is formed by alternately laminating green piezoelectric sheets 130g corresponding to the piezoelectric layers 130 and green electrode films 131g corresponding to the internal electrodes 131. The green piezoelectric sheets 130g are formed by shaping a paste including the piezoelectric material with the use of one of well-known approaches such as a doctor blade method. The green electrode films 131g are formed onto the green piezoelectric sheets 130g by shaping a paste including a material of the internal electrodes 131 with the use of one of well-known approaches such as screen printing, spray coating, and ink-jet printing. In order to further ensure the adhesion between the green piezoelectric sheets 130g and the green electrode films 131g, green adhesive layers may be interposed between the green piezoelectric sheets 130g and the green electrode films 131g. In this case, the green adhesive layers are formed onto the green piezoelectric sheets 130g with the use of one of well-known approaches such as coating.

The green electrode films 140g are also formed respectively onto the upper and lower surfaces 160g, 161g of the green laminated body part 110g by shaping a paste including a material of the surface electrode 140 with the use of one of well-known approaches such as screen printing, spray coating, and ink-jet printing. Specifically, for example, this paste includes a powder of an electrode material such as platinum or palladium, a binder, a dispersion medium, and a solvent. Ethyl cellulose, polyvinyl alcohol, an acrylic resin, or the like can be used as the binder, and terpineol, texanol, isopropyl alcohol, or the like can be used as the solvent. This paste may contain therein a gold powder. The powder of the electrode material (and the gold powder) are, for example, 0.1 to 2.0 μm in particle size.

Then, machining such as cutting and punching is applied along cutting-plane lines (see dashed-two dotted lines) 310 as shown in FIG. 3. As a result, as shown in FIG. 4, on the base material 300, the multiple (3×7) green piezoelectric device corresponding parts 100g can be extracted in the same step. Hereinafter, for the convenience of explanation, attention will be focused on only one of the multiple green piezoelectric device corresponding parts 100g extracted, and the explanation will be continued.

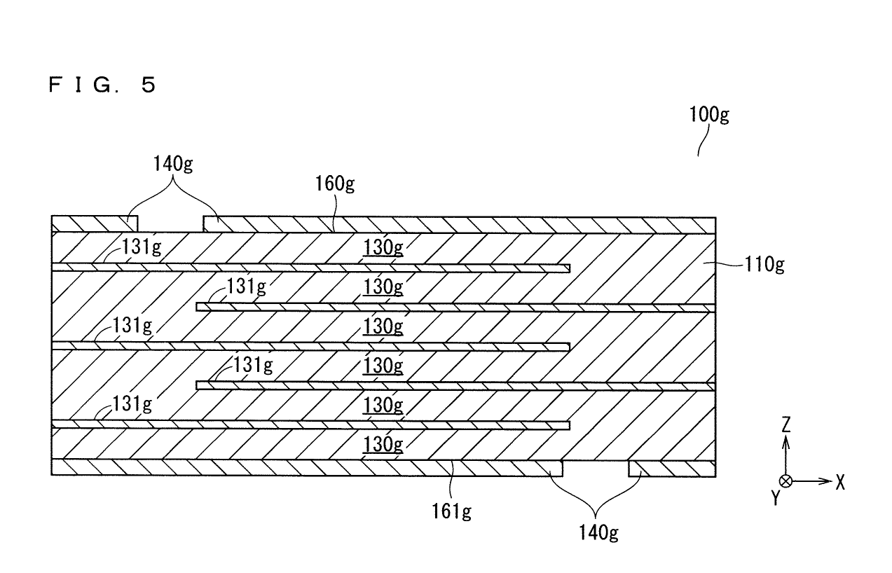

FIG. 5 shows a cross section of one green piezoelectric device corresponding part 100g extracted, which corresponds to FIG. 2. As shown in FIG. 5, in this example, the green piezoelectric device corresponding part 100g is composed of: the green laminated body 110g corresponding to the main body part 110; and the green electrode films 140g, 140g corresponding to the surface electrode 140, which are formed on the upper and lower surfaces 160g, 161g of the green laminated body 110g. The green laminated body 110g is a laminated body with the piezoelectric sheets 130g located as uppermost and lowermost layers, and the piezoelectric sheets 130g and electrode films 131 g laminated alternately.

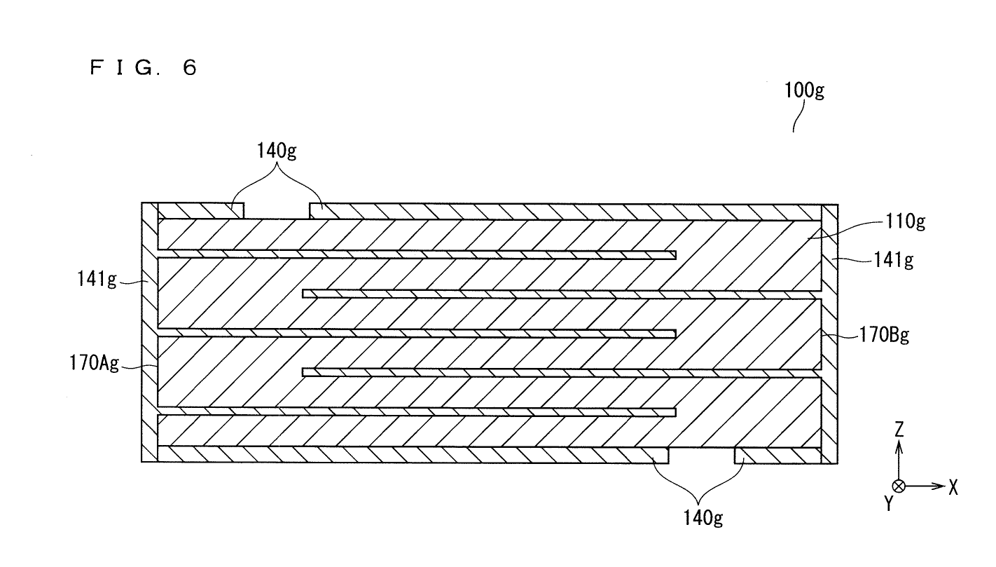

Next, as shown in FIG. 6, green electrode films 141g corresponding to the side-surface electrode 141 are formed on predetermined sites of side surfaces 170Ag, 170Bg of the green piezoelectric device corresponding part 100g. The green electrode films 141g are also formed by shaping a paste including a material of the side-surface electrode 141 with the use of one of well-known approaches such as screen printing, spray coating, and ink-jet printing. Specifically, for example, this paste includes a powder of an electrode material such as platinum or palladium, a binder, a dispersion medium, and a solvent. Ethyl cellulose, polyvinyl alcohol, an acrylic resin, or the like can be used as the binder, and terpineol, texanol, isopropyl alcohol, or the like can be used as the solvent. This paste contains therein a gold powder. The powder of the electrode material and the gold powder are, for example, 0.1 to 2.0 μm in particle size.

Then, the green piezoelectric device corresponding part 100g shown in FIG. 6 is subjected to firing at a predetermined temperature (for example, 900 to 1200° C.) for a predetermined period of time (for example, the maximum temperature holding time is 0.5 to 3 hours). In other words, the green laminated body 110g (the green piezoelectric sheets 130 corresponding to the piezoelectric layers 130 and the green electrode films 131g corresponding to the internal electrodes 131) corresponding to the main body part 110, as well as the green electrode films 140g corresponding to the surface electrode 140 and the green electrode films 141g corresponding to the side-surface electrode 141 is subjected to co-firing. As a result, the piezoelectric device 100 (fired) shown in FIGS. 1 and 2 is obtained.

It is to be noted that the large green laminated body 301 with the electrode films 140g formed is subjected to machining in the example described above. As a result, as shown in FIG. 5, at the stage of having extracted each green piezoelectric device corresponding part 100g by the machining, the corresponding part 100g has the electrode films 140g already formed. In contrast, the large green laminated body 301 without any electrode film 140g formed may be subjected to machining. In this case, after the extraction of each green piezoelectric device corresponding part 100g by the machining, for each green piezoelectric device corresponding part 100g, the electrode films 140g can be formed, and thereafter, the electrode films 141g can be formed. Alternatively, for each green piezoelectric device corresponding part 100g, the electrode films 141g may be formed, and thereafter, the electrode films 140g may be formed.

(Example of Mounting Piezoelectric Device)

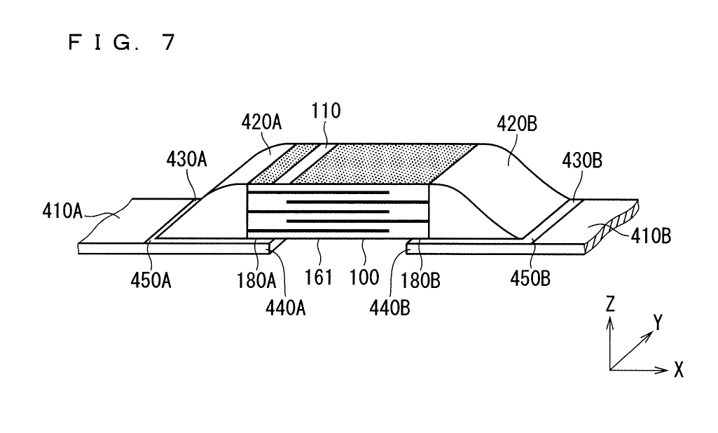

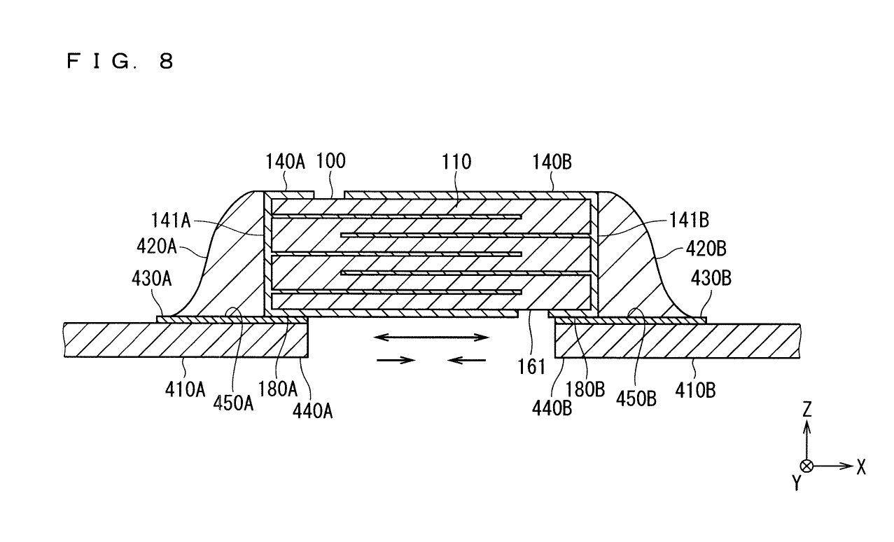

The piezoelectric device 100 described above according to the present preferred embodiment is mounted on substrates 410A, 410B with the use of solder parts 420A, 420B, for example, as shown in FIGS. 7 and 8. In this example, first, both ends 180A, 180B of the lower surface 161 of the piezoelectric device 100 are placed respectively on upper surfaces 450A, 450B of opposed ends 440A, 440B of the pair of substrates 410A, 410B located away from each other (more specifically, upper surfaces of copper ends 430A, 430B provided on the upper surfaces 450A, 450B of the ends 440A, 440B). Next, the pair of side-surface electrodes 141A, 141B of the piezoelectric device 100 and the ends 440A, 440B of the pair of substrates 410A, 410B are joined and fixed with the use of the solder parts 420A, 420B. Thus, the mounting of the piezoelectric device 100 onto the pair of substrates 410A, 410B is completed.

In the piezoelectric device 100 mounted onto the pair of substrates 410A 410B, the deformation amount of the piezoelectric layers 130 (thus, the main body part 110) is changed (see the arrows shown in FIG. 8) by varying the potential difference applied between the first and second electrode groups 150A 150B. As a result, the distance (interval) is changed between the pair of substrates. Through the use of this principle, the piezoelectric device can be used as an actuator that controls the position of an object such as an optical lens. Alternatively, in the piezoelectric device 100 thus mounted onto the pair of substrates 410A, 410B, the deformation amount of the piezoelectric layers 130 (thus, the main body part 110) is changed (see the arrows shown in FIG. 8) by varying the magnitude of a force applied to the pair of substrates 410A, 410B in the direction of changing the distance (interval) between the substrates 410A, 410B, and the potential difference produced between the first and second electrode groups 150A, 150B varies depending on the deformation amount. Through the use of this principle, the piezoelectric device 100 can also be used as various types of sensors such as a mass sensor.

(Action and Effect)

In the mounting of the piezoelectric device as described above, it is suitable to use, as the solder, the above-described “low-melting-point solder” (solder with a melting point of 200° C. or lower). The low-melting-point solder typically includes tin (Sn), bismuth (Bi), and silver (Ag). The use of the low-melting-point solder provides various advantages as described in the section “SUMMARY OF THE INVENTION,” due to the fact that the step of joining can be carried out with the use of (melted) solder at a relatively low temperature.

However, in general, the “low-melting-point solder” has relatively low wettability to platinum or palladium, and thus, when the side-surface electrode of the piezoelectric device is composed of only platinum or palladium, the (melted) “low-melting-point solder” is less likely to spread on the surface of the side-surface electrode. Therefore, the joint area between the side-surface electrode and the “low-melting-point solder” is reduced, thereby probably resulting in a problem of decreased reliability for the joint between the side-surface electrode and the “low-melting-point solder.”

For this problem, the inventors have made various experiments and researches, in order to improve the reliability for the joint between the side-surface electrode and the “low-melting-point solder.” As a result, the inventors have found that when the side-surface electrode is composed of platinum or palladium, the side-surface electrode containing gold therein improves the reliability for the joint between the side-surface electrode and the “low-melting-point solder,” as compared with when the side-surface electrode is composed of only platinum or palladium, and the reliability for the joint is strongly correlated with the content ratio of gold in the side-surface electrode. A test for confirming the foregoing will be described below.

(Test)

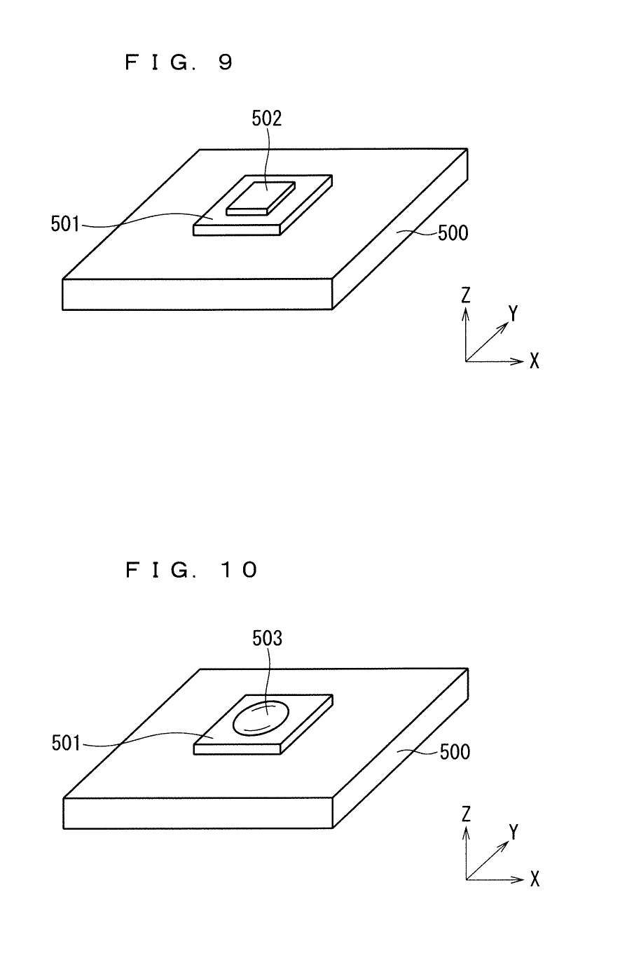

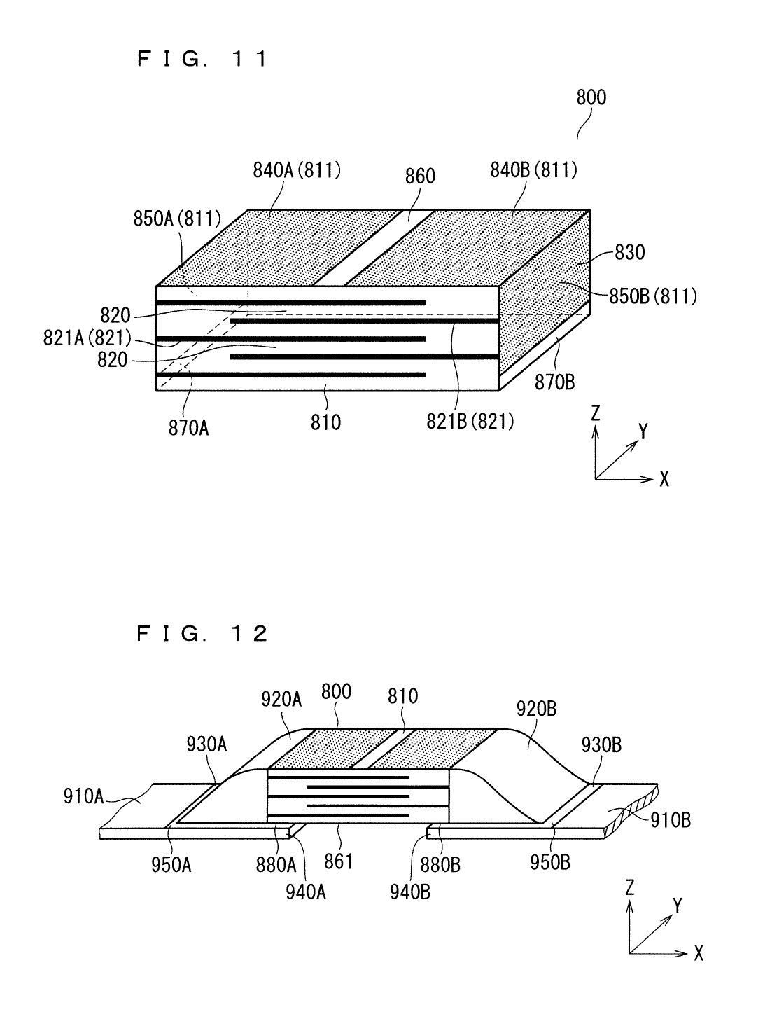

In this test, a device having a form shown in FIG. 9 (before reflow) and FIG. 10 (after reflow) was used as a sample. In this sample, a piezoelectric plate 500 and an electrode plate 501 respectively correspond to the main body part 110 (piezoelectric layers 130) and the side-surface electrode 141 of the piezoelectric device 100 shown in FIG. 1. The piezoelectric plate 500 has the thin rectangular solid-like shape with 10 mm×10 mm square and 0.3 mm thick. The electrode plate 501 has the thin rectangular solid-like shape with 5 mm×5 mm square and 5 μm thick. Low-melting-point solder 502 (before reflow) shown in FIG. 9 is a solder paste formed in a region 1 mm×1 mm square and 0.1 mm thick.

This sample was prepared in the following way. First, a green sheet was formed with the use of a piezoelectric paste including a powder of a piezoelectric material. Specifically, for example, a piezoelectric paste obtained by adding a solvent, a binder, and a plasticizer to a powder of a piezoelectric material was mixed with the use of a ball mill. A mixed solvent of xylene and butanol was used as the solvent, PVB was used as the binder, and DOP was used as the plasticizer. Next, the mixed piezoelectric paste was applied onto PET films by a doctor blade method, thereby forming piezoelectric green sheets.

Next, an electrode paste including a powder of an electrode material was shaped on upper surfaces of the piezoelectric green sheets with the use of screen printing or the like, thereby forming (laminating) a compact for the electrode plate. A platinum powder with a gold powder mixed therein was used as the powder of the electrode material. The platinum powder was 0.3 to 0.7 μm in particle size (before firing), and the gold powder was 0.3 to 0.7 μm in particle size (before firing). Ethyl cellulose was used as a binder for the electrode paste, and texanol was used as a solvent for the electrode paste.

Then, the unfired laminated body was subjected to co-firing. The firing temperature was 1100° C., and the firing time was 2 hours. Then, the low-melting-point solder 502 before reflow was placed on the fired electrode plate 501. Thus, the sample shown in FIG. 9 was obtained. PF142-LT7 (NIHON HANDA Co., Ltd.: Sn-57Bi-1Ag) was used as the low-melting-point solder.

This sample shown in FIG. 9 was subjected to reflow (heating) for the low-melting-point solder. Specifically, first, preliminary heating was carried out over 80 seconds at 120 to 130° C. Thereafter, the temperature was continuously increased so that the heating time at 140° C. or higher was 80 seconds or more in total. The maximum temperature during the heating was 195° C. As a result, as shown in FIG. 10, the low-melting-point solder 503 was melted and deformed, and the low-melting-point solder 503 was joined onto an upper surface of the electrode plate 501 (soldering completed).

In this test, the thus soldered sample was evaluated for “Wettability of Low-melting-point Solder,” “Condition of Co-fired Electrode Plate,” and “Peeling of Low-melting-point Solder.” The “Wettability of Low-melting-point Solder” was evaluated by measuring the magnitude of the contact angle of the low-melting-point solder to the upper surface of the electrode plate (the wettability is better as the contact angle is smaller). The “Condition of Co-fired Electrode Plate” was evaluated by determining whether or not the electrode plate underwent agglomeration by firing (the condition of the electrode plate is better without any agglomeration). The “Peeling of Low-melting-point Solder” was evaluated in a simplified way with the use of a tape test method. Specifically, an adhesive tape (Scotch tape (from 3M)) was attached to the upper surface of the low-melting-point solder by pushing with a finger for 10 seconds, and thereafter, the tape was peeled instantaneously in a direction perpendicular to the attachment surface. Thus, the low-melting-point solder was peeled from the electrode plate. Then, the peeled interface of the low-melting-point solder peeled was observed.

In this test, prepared were multiple samples with varying content ratios (Au content ratio, weight %) of gold (Au) in the electrode plates. Specifically, as shown in Table 1, eleven types of levels were prepared. Ten samples (N=10) were prepared for each level.

TABLE 1

| | Material of | Material of | Au Content | | Condition | |
|---|---|---|---|---|---|---|
| | Low-Melting- | Electrode | Ratio | Solder | of Co-fired | Peeling |
| Level | Point Solder | Plate | (weight %) | Wettability | Electrode Plate | of Solder |
| 1 | PF142-LT7 | Pt | 0 | X | ◯ | X |
| 2 | PF142-LT7 | Pt + Au | 1 | X | ◯ | X |
| 3 | PF142-LT7 | Pt + Au | 2 | X | ◯ | X |
| 4 | PF142-LT7 | Pt + Au | 3 | ◯ | ◯ | ◯ |
| 5 | PF142-LT7 | Pt + Au | 4 | ◯ | ◯ | ◯ |
| 6 | PF142-LT7 | Pt + Au | 5 | ⊙ | ◯ | ◯ |
| 7 | PF142-LT7 | Pt + Au | 10 | ⊙ | ◯ | ◯ |
| 8 | PF142-LT7 | Pt + Au | 15 | ⊙ | ◯ | ◯ |
| 9 | PF142-LT7 | Pt + Au | 20 | ⊙ | Δ | ◯ |
| 10 | PF142-LT7 | Pt + Au | 30 | — | Failure to | — |
| | | | | | Retain Shape of | |
| | | | | | Electrode Plate | |
| 11 | PF142-LT7 | Pt + Au | 40 | — | Failure to | — |
| | | | | | Retain Shape of | |
| | | | | | Electrode Plate | |

The “Au Content Ratio (weight %)” in Table 1 refers to the proportion (%) of “the total weight of Au in the side-surface electrode” to “the total weight of the side-surface electrode.” The value of the “Au Content Ratio” listed for each level in Table 1 refers to a value (average value for N=10) after the firing. In Table 1, a conventional composition (Au Content=0%) with “a side-surface electrode composed of only platinum without containing Au” was adopted only for Level 1. The Au content ratio was adjusted by the amount (ratio by weight) of the gold powder mixed in the electrode paste mentioned above.

Then, the ten samples were each subjected to the evaluations described above for each level. In Table 1, as for the “Solder Wettability,” the mark “x” refers to a contact angle larger than 90°, the mark “0” refers to a contact angle of approximately 90°, and the mark “0” refers to a contact angle smaller than 90°. As for the “Condition of Co-fired Electrode Plate,” the mark “0” refers to no agglomeration found in the electrode plate, and the mark “A” refers to agglomeration found partially in the electrode plate. As for the “Peeling of Solder,” the mark “x” refers to peeling caused between the electrode plate and the solder in one or more samples, and the mark “0” refers to no sample with peeling caused between the electrode plate and the solder. It is to be noted that at Levels 10, 11, agglomeration was caused excessively in the electrode plate during co-firing, thereby making the electrode plate fail to retain its shape, and thus resulting in failure to obtain any sample. Accordingly, the respective evaluations were not able to be carried out.

As can be understood from Table 1, it can be determined that when the Au content ratio is 3 weight % or more (see Levels 4 to 9), the low-melting-point solder is less likely to be peeled with better wettability, as compared with when the Au content ratio is less than 3 weight % (see Levels 1 to 3). In addition, when the Au content ratio is 5 weight % or more, the low-melting-point solder has particularly good wettability. When the Au content ratio is 15% or less, the co-fired electrode plate has a particularly good condition. It is to be noted that as described above (see also Table 1), when the Au content ratio exceeds 20 weight %, the shape of the electrode plate is unable to be retained due to agglomeration in the electrode plate. Accordingly, the Au content ratio is desirably 3 weight % or more and 20 weight % or less, further desirably 5 weight % or more and 20 weight % or less, particularly desirably 5 weight % or more and 15 weight % or less. The Au content ratio may be 3 weight % or more and 15 weight % or less.

As just described, the fact the electrode plate composed of platinum with gold therein improves reliability for the joint between the electrode plate and the “low-melting-point solder” as compared with that without gold therein is assumed to be based on the following reason.

That is, as can be easily understood from a phase diagram (not shown) of gold (Au) and tin (Sn), it is known that in the case of gold (Au) in contact with tin (Sn) in the low-melting-point solder, gold and tin form an alloy phase even at a relatively low temperature on the order of 200° C. Therefore, in the case of the electrode plate composed of platinum with gold therein, when the melted “low-melting-point solder” at approximately 200° C. comes into contact with the surface of the electrode plate, the gold in the electrode plate can be dissolved in the melted “low-melting-point solder.” Due to the solution of gold, the platinum present around the dissolved gold is also more likely to be dissolved in the melted “low-melting-point solder.” As a result, a compound layer including at least tin and platinum can be formed at the joint part between the electrode plate and the “low-melting-point solder.” The formation of this compound layer is assumed to improve the reliability for the joint between the electrode plate and the “low-melting-point solder.” In other words, the gold in the electrode plate is assumed to function as “an aid that dissolves platinum in the electrode plate to form a compound layer,” thereby improving the reliability for the joint between the electrode plate and the “low-melting-point solder.”

When the Au content ratio is less than 3 weight %, the solder is poor in wettability and likely to be peeled as compared with when the Au content ratio is 3 weight % or more. This is believed to be due to the fact “the aiding function of gold” cannot be sufficiently fulfilled because of the excessively low Au content ratio. In addition, when the Au content ratio exceeds 20 weight %, agglomeration is excessively caused during the firing, thereby making the electrode plate fail to retain its shape. This is believed to be due to the fact that the Au content ratio is excessively high, thereby decreasing the melting point of the whole electrode plate.

As just described, the side-surface electrode composed of platinum with gold therein improves the reliability for the joint between the side-surface electrode and the “low-meting-point solder,” as compared with when the side-surface electrode is composed of only platinum. Furthermore, when the Au content ratio of the side-surface electrode is 3 to 20 weight %, the reliability for the joint is further improved.

While an example of using platinum as a material of the electrode plate has been provided above in the experiment mentioned above, it has been separately confirmed that exactly the same result is obtained also when palladium is used in place of platinum as a material of the electrode plate. More specifically, the electrode plate composed of palladium with gold therein improves the reliability for the joint between the electrode plate and the “low-melting-point solder,” as compared with when the electrode plate is composed of only palladium. Furthermore, when the Au content ratio of the electrode plate is 3 to 20 weight %, the reliability for the joint is further improved. Furthermore, it has been separately confirmed that exactly the same result is obtained when an alloy of platinum and palladium is used in place of platinum as a material of the electrode plate.

The present invention is not limited to the preferred embodiment mentioned above but various modification examples can be adopted within the scope of the present invention. For example, in the preferred embodiment mentioned above, the side-surface electrode 141 composed of platinum or palladium contains gold therein, and the low-melting-point solder is joined to the side-surface electrode 141. However, the surface electrode 140 composed of platinum or palladium may contain gold therein, and the low-melting-point solder may be joined to the surface electrode 140.

In addition, while the main body part 110 is a laminated body that has the piezoelectric layers 130 and internal electrodes 131 laminated alternately in the preferred embodiment mentioned above, the main body part 110 may be a piezoelectric body composed of only a piezoelectric material (without any internal electrode). In addition, the main body part 110 may be a ceramic body composed of only a ceramic material other than piezoelectric materials (without any internal electrode).

It is to be noted that it has been separately confirmed that the reliability for the joint between the external electrode and the low-melting-point solder is improved even when silver (Ag) or copper (Cu) is added in place of gold (Au) in the case of the external electrode composed of platinum (Pt). This is also assumed to be based on the same mechanism as in the case of gold. More specifically, in the case of the external electrode composed of platinum with “silver or copper” therein, when the melted “low-melting-point solder” at approximately 200° C. comes into contact with the surface of the external electrode, the “silver or copper” in the external electrode is dissolved in the melted low-melting-point solder, thereby forming an alloy phase of “silver or copper” and tin. Due to the dissolution of “silver or copper,” platinum present around the “silver or copper” dissolved is also dissolved in the melted low-melting-point solder, and as a result, a compound layer including at least tin and platinum can be formed at the joint part between the external electrode and the “low-melting-point solder.” The formation of the compound layer is assumed to improve the reliability for the joint between the external electrode and the “low-melting-point solder.” In other words, the “silver or copper” in the external electrode is assumed to function as “an aid that dissolves platinum in the external electrode to form a compound layer,” thereby improving the reliability for the joint between the external electrode and the “low-melting-point solder.”

While the invention has been shown and described in detail, the foregoing description is in all aspects illustrative and not restrictive. It is therefore understood that numerous modifications and variations can be devised without departing from the scope of the invention.

What is claimed is:

1. A ceramic device as a fired body, comprising:
a main body part having a surface and including a part of a ceramic material; and
an external electrode partially covering said surface, including one or both of platinum and palladium, and further including gold.

2. The ceramic device according to claim 1,
wherein said surface has upper and lower surfaces and a side surface,
said external electrode is a side-surface electrode at least partially covering said side surface, and
said ceramic device further comprises a surface electrode that at least partially covers said upper and lower surfaces and is connected to said side-surface electrode.

3. The ceramic device according to claim 2,
wherein said surface electrode includes one or both of platinum and palladium, and further includes gold.

4. The ceramic device according to claim 1,
wherein said surface has upper and lower surfaces and a side surface,
said external electrode is a surface electrode at least partially covering said upper and lower surfaces, and
said ceramic device further comprises a side-surface electrode that at least partially covers said side surface and is connected to said surface electrode.

5. The ceramic device according to claim 1,
wherein said ceramic material is a piezoelectric material,
said ceramic device functions as a piezoelectric device,
said main body part is a laminated body obtained by laminating at least two piezoelectric layers of said piezoelectric material, and at least one internal electrode.

6. The ceramic device according to claim 1,
wherein a content ratio of gold in said external electrode is 3 to 20 weight %.

7. The ceramic device according to claim 1,
wherein said main body part and said external electrode are obtained by co-firing.

8. A joined body comprising:
the ceramic device according to claim 1;
a substrate; and
solder that joins an external electrode of said ceramic device to said substrate, and has a melting point lower than 200° C.
